(19) United States
(12) Patent Application Publication
(10) Pub. No.: US 2002/0067184 A1
(43) Pub. Date: Jun. 6, 2002

(54) Method and apparatus for testing color sequential, near-to-the-eye, and similar display devices

(75) Inventors: Pete Smith, Chandler, AZ (US); Daniel Hoffman, Apache Junction, AZ (US); Edward Douglass Patterson, Mesa, AZ (US); Andrew R. Slater, Phoenix, AZ (US)

Correspondence Address: Merchant & Gould P.C., P.O. Box 2903, Minneapolis, MN, 55402-0903, US

(73) Assignee: Three-Five Systems, Inc.

(21) Appl. No.: 09/916,616

(22) Filed: Jul. 26, 2001

Related U.S. Application Data
(60) Provisional application No. 60/244,125, filed on Oct. 27, 2000.

(51) Int. Cl. G01R 31/00

(52) U.S. Cl. 324/770

(57) ABSTRACT

A test method and apparatus for liquid crystal display (LCD) devices, and in particular LCoS (liquid crystal on silicon) display devices, to achieve a pass/fail determination based upon user-defined tolerances of the LCD devices. The test apparatus side-illuminates the LCD device to provide reliable pixel defect detection and uniformity measurement. The test method is adaptable for LCD devices that have light emitting devices (LEDs) integrated into the LCD or separated from the LCD. The side-illumination provides a gradient of brightness that is further discernable into red, green, and blue colors. A monochromatic image can be driven by the LEDs using one of two drive schemes. The first drive scheme illuminates a single color according to a monochrome test mode. The second drive scheme drive a white image with a single LED illuminated such that a monochromatic image results. A module can reorder the testing according to the rate of failures for each test.

### FIELD OF THE INVENTION

The present invention relates to liquid crystal displays and similar electro-optical devices. More specifically, the present invention relates to hardware and software methods used in production testing liquid crystal display devices, and even more specifically to production testing color sequential, near-to-the-eye, and/or digital backplane display devices.

### BACKGROUND OF THE INVENTION

Liquid crystal displays (LCDs) and, in particular, liquid crystal on silicon (LCoS™) displays are being produced in relatively large volumes to meet an increasing demand. Typical conventional LCD test equipment provides only measurements of the performance of an LCD. However, in a manufacturing environment, only a pass/fail determination need be made rather than performance characterizations. Thus, in the manufacturing environment, conventional LCD test equipment relies on an operator to analyze the performance measurements to determine whether the LCD is suitable for sale to customers (i.e., to make the pass/fail determination). These conventional test systems tend to be a bottleneck in the manufacturing process, which is undesirable in a high volume production environment where speed is crucial to profitability. In addition, conventional LCD test equipment does not test a number of parameters that are useful in determining whether an LCD device is suitable for sale, such as pixel defects or uniformity.

Therefore, there is a need for a test system that is suitable for use in a high volume LCD production environment and that more accurately determines the suitability of LCD devices for sale to customers.

### SUMMARY OF THE INVENTION

Briefly stated, the present invention provides a method and apparatus for testing liquid crystal display (LCD) devices, and in particular LCoS display devices, to achieve a pass/fail determination based on certain manufactured parameters of the LCD devices. The present invention enables reliable pixel defect detection and pixel uniformity detection through the use of a side-illuminated test apparatus. The test apparatus may be equally adapted for display devices having LEDs (light emitting devices) configured integral to a liquid crystal module (LCM) as well as devices having an LCM without integral LEDs.

The side-illumination provided by the test apparatus in accordance with the present invention causes a gradient brightness to be imparted to a device under test. The gradient in brightness can be discerned in the test apparatus further into red, green, and blue components (based on the proper selection of LEDs). The brightness and color can be controlled via appropriate driving schemes. A monochromatic image can be driven by the tester with the two of the three LEDs turned off. Alternatively, one of the three LEDs can be fired at each time interval. The gradient brightness is then received by the test apparatus and analyzed by a controller, such as a computing system, to make a pass/fail determination of each device under test. The test can be repeated for the remaining two of the three LED's if necessary.

In another aspect of the invention, the method and apparatus makes possible additional tests that may be performed to help identify suitable LCD devices. It is possible to perform both uniformity tests and pixel defect tests on devices that make use of the side-illuminated test apparatus. The uniformity tests provide a measure of the degree to which individual pixels in the device deviate from a nominal gray level driven into the device. For pixel defect detection, a single pixel is examined for variations in nominal operation by examining the gray level difference between the pixel's actual gray level and the nominal gray level driven by the LCD device. Both tests can provide a pass/fail determination for the LCD device.

In yet another aspect of the invention, a tester in accordance with the present invention is capable of testing a digital device over a discrete number of gray levels using a process of histogram equalization. An initial or sample histogram of the gray levels of the LCD image is taken and compared to the nominal gray levels. This method can reach a pass/fail decision for the LCD quickly with a reduced requirement in complexity for the test apparatus.

In yet another aspect of the invention, as more LCD devices are tested, a module can adjust the testing such that the portion if the test revealing the highest failure rate can be performed earlier. Reordering the testing according to the rate of failures for each test further increases the speed of the overall testing process.

### BRIEF DESCRIPTION OF THE DRAWINGS

FIG. 1 is a functional block diagram illustrating one exemplary embodiment of a test apparatus employing side-illumination that may implement the present invention.

FIGS. 2-5 illustrate additional illustrative components of one actual embodiment of an LCD test apparatus constructed in accordance with the teachings of the present invention.

FIGS. 6-8 are device driving schemes that may be employed during the testing of devices by the tester of FIG. 1, in accordance with one embodiment of the present invention.

FIGS. 9A and B are a flow chart that illustrates a process for operating a tester in accordance with the invention in a first-fail detection mode that includes a genetic (learning) module to improve throughput.

### DETAILED DESCRIPTION OF THE PREFERRED EMBODIMENT

In a high volume LCD production environment, the inventors of the present invention have appreciated that it is desirable that tests and test equipment provide pass/fail indications, in addition to measurements of performance. As used herein, “LCD devices” includes LCoS™ devices available from Three-Five Systems, Inc., of Tempe, Ariz. LCD test equipment currently available from vendors provides what is referred to herein as “characterization data”. That is, the data provided are measurements of certain vendor-selected parameters, without any mechanism, means or intelligence to determine whether the measured parameter is with a specified tolerance. Rather, the determination is made by an operator. Such test equipment cannot be easily automated. The costs involved in such a test system are relatively high and generally result in a throughput bottleneck in a high volume production environment.

In accordance with the present invention, a tester is configured to be programmable with user-defined tolerances for various parameters measured by the tester. In addition, the tester is configured to compare the measured parameters to the user-defined tolerances in an automated test process to provide a pass/fail indication for the LCD. In a further refinement, the tester is configured to provide additional processing of some measurements (e.g., brightness vs. LCD control voltage measurements) to provide a parameter (e.g., the derivative of the brightness vs. LCD control voltage curve) that can be easily compared to a predetermined tolerance for that parameter.

The aforementioned conventional testers typically require manual insertion of an LCD into the tester, which makes impractical automating the testing process. To facilitate automated testing and to provide protection for LCD parts while being transported and loaded into the tester, a tray or rail (not shown) according to the present invention is used. In one embodiment, the tray is designed to hold several LCD devices. The tester, according to the present invention is correspondingly adapted to accept and handle the trays. By handling the trays instead of the LCDs directly, the test process can be automated with reduced risk of damaging the LCDs.

Advantages with Side-Illuminated Devices

Conventional test equipment does not provide a solution for testing LCD devices that involve side-illuminating LED sources. Rather, conventional LCD test equipment employs illumination coaxial with the LCD device, which fails to reliably test the device in its intended mode of operation. The concentric lighting creates difficulties in the measurement of uniformity and determining gray scale differences (i.e., pixel level defects) of an LCD device.

In contrast, a tester constructed in accordance with the present invention provides many advantages to testing side-illuminated devices. For instance, where a single illumination (white) source is used, the multiplexer under each pixel of the LCD may be untested for opens and shorts. For color sequential systems, the single illumination source is only on at the time the selected color is on to check multiplexer operation. This type of single illumination source is unable to test for color uniformity without a color filter system used to separate each color for testing. A tester according to the present invention is configured to test the multiplexer under each pixel for opens and shorts without a color filtration system.

Importantly, the inventors have determined that proper side-illumination of the device under test device makes it possible to reliably perform the additional tests of pixel defect detection and uniformity detection for color-sequential devices. The effect of gradient illumination originating from side-mounted LEDs has not previously been investigated. The inventors have determined that side-illumination allows uniformity to be measured using a CCD to capture the reflected light over an area for color-sequential devices. Alternatively, a spectrometer can collect the reflectance versus wavelength for predefined areas. Side illumination is comparable to a passive matrix LCD light guide or lightbar. However, passive matrix LCD light guides or lightbars are product configurations and not test configurations as in the present invention.

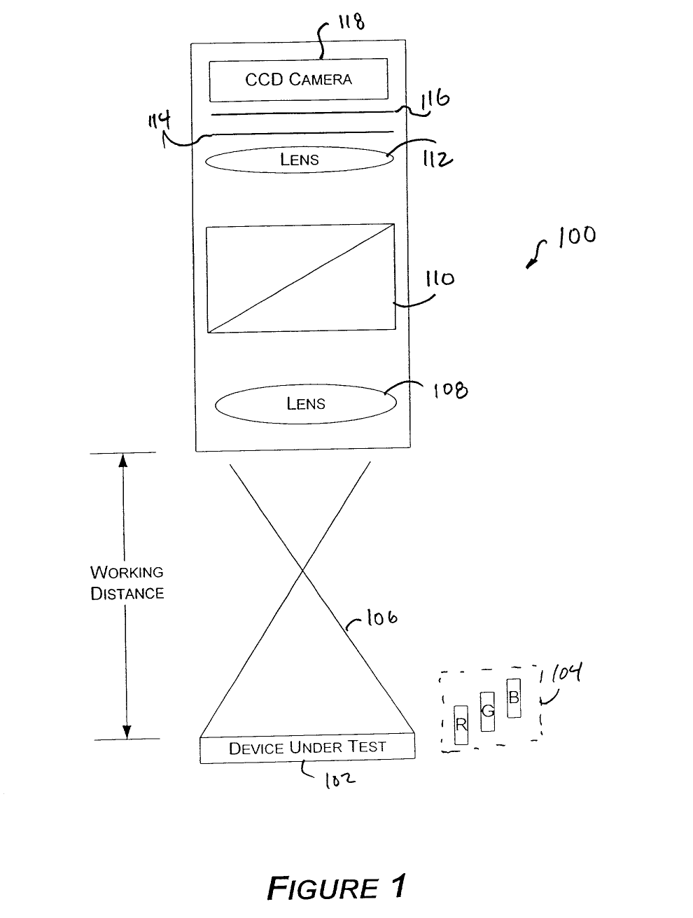

FIG. 1 illustrates one exemplary test apparatus 100 for optical evaluation of test devices. As shown in FIG. 1, device under test 102, such as a LCM, is side-illuminated (rather than coaxially illuminated) by a package of LEDs 104. This illumination configuration differs from conventional test apparatus that typically makes use of a light source (not shown) illuminating the device under test 102 through the polarizing beam splitter 110. In accordance with this embodiment, the LEDs are configured to emit light of certain colors, typically red, green, and blue. Light 106 emitted by the device under test 102 is received by a camera device 118. In the camera device, the light 106 is focused by a first lens 108 to pass through a polarizing beam splitter 110, and is then refocused by a second lens 112. The refocused light then passes through a polarizer 114 and a photopic filter 116 before being received at a CCD camera 118. Typical LCD test equipment uses CCD cameras having a relatively high resolution compared to the resolution of the LCD to measure parameters of a test image displayed by the LCD under test.

The side illumination of the LEDs 104 causes a gradient brightness to be imparted to the device under test 102. The gradient in brightness can be discerned in the test application further into red, green, and blue components (based on the LEDs 104). The brightness can be controlled via appropriate driving schemes (described in greater detail below). A first scheme drives a white image by the tester with two of the three LEDs 104 turned off such that a single color illuminates the LCD device 102. This driving scheme suffers from a slight disadvantage in that the total test time may be longer than with other driving schemes. Alternatively, one of the three LEDs 104 can be fired at each time interval, in a monochrome mode, to achieve a similar result with a faster test time. From this discussion, it is appreciated and understood that more LEDs 104 of various colors could be used for illumination in the present invention.

Some test devices 102 may be self-contained (e.g., the LEDs 104 are part of the display package). Others may have the LEDs 104 incorporated into the optics or liquid crystal module (LCM) of the device under test 102. The test apparatus 100 according to the present invention is uniquely adapted to test both configurations. In other words, the LEDs 104 of the test apparatus 100 may be integral to the test apparatus itself (in the case where the LEDs 104 of the device are not part of the LCM). Alternatively, the LEDs 104 used in the test apparatus 100 may be those that are integral to the device under test 102 in the case where the device is self-contained. The advantage of this test apparatus 100 for the self-contained products (those having a liquid crystal module with integral LEDs) is that the uniformity of the LCM and the LEDs 104 are both directly tested. The customer is assured that an acceptable product has been produced. In addition, the effect of the gradient in the illumination of the LCM can be removed by performing periodic calibration of the LEDs 104 of the test apparatus 100 with respect to a first surface mirror and quarter wave plate. This approach would be used in the test configuration with LEDs 104 fixed to the test apparatus 100.

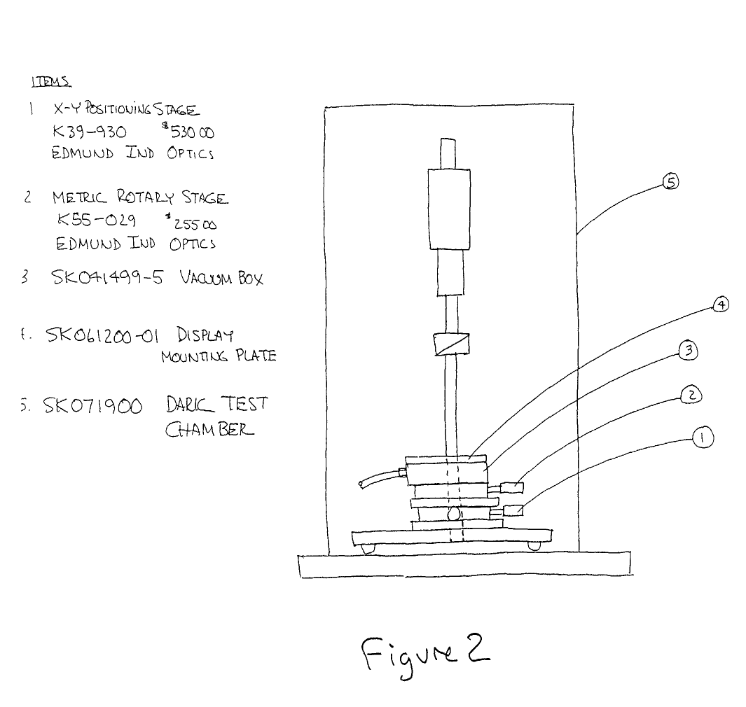

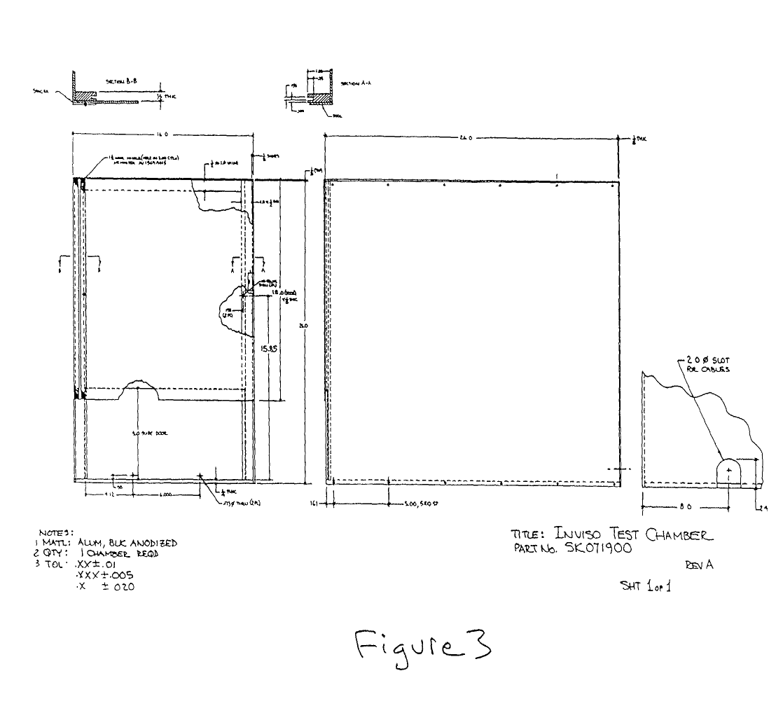

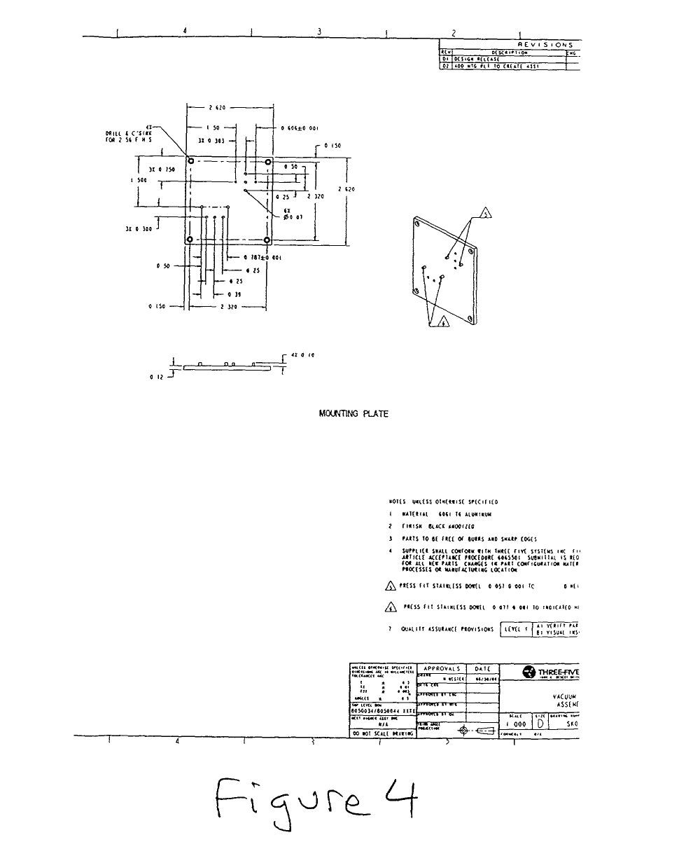

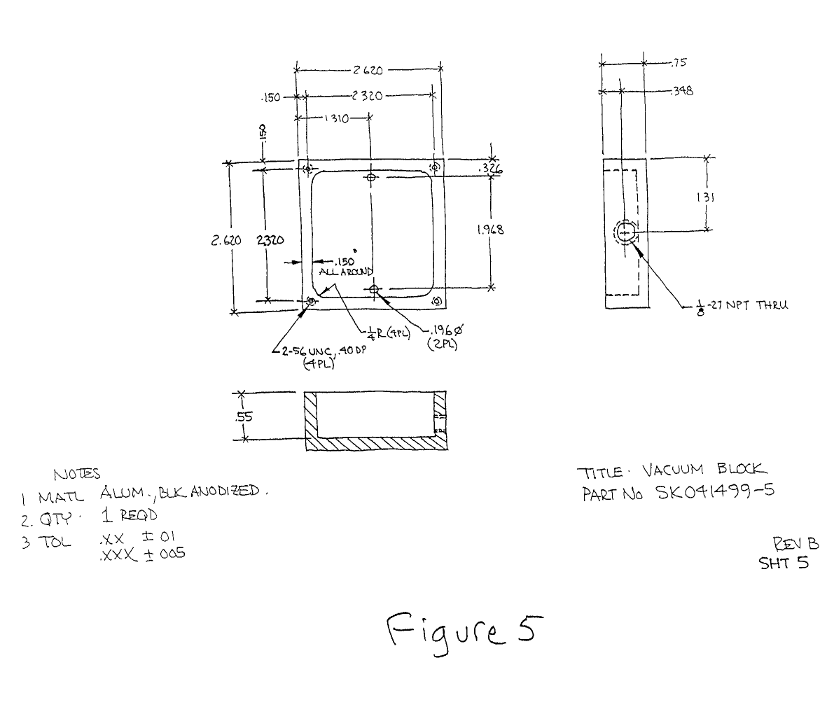

The illumination intensity (such as by the LEDs 104) decreases over time. The LED 104 degradation is well characterized. A lifetime degradation function can be employed in the test apparatus 100 in many ways, such as by describing a function used in continual calibration or by rendering the test apparatus 100 inoperable after a number of uses. FIGS. 2-5 illustrate additional illustrative components of one actual embodiment of an LCD test apparatus constructed in accordance with the teachings of the present invention.

The inventors have noted that in certain types of color sequential devices, the illumination color is modulated in time. The inventors have determined that this feature poses unique challenges for determining the color, uniformity, and brightness measure, and identifying the presence of pixel defects (or more appropriately, gray scale differences from a nominally driven value). Further, the illumination (often an LED) intensity decreases over time and may be configured in an off-axis mode. The test apparatus 100 constructed in accordance with the present invention is uniquely configured to test those more difficult parameters.

Driving Schemes for Test

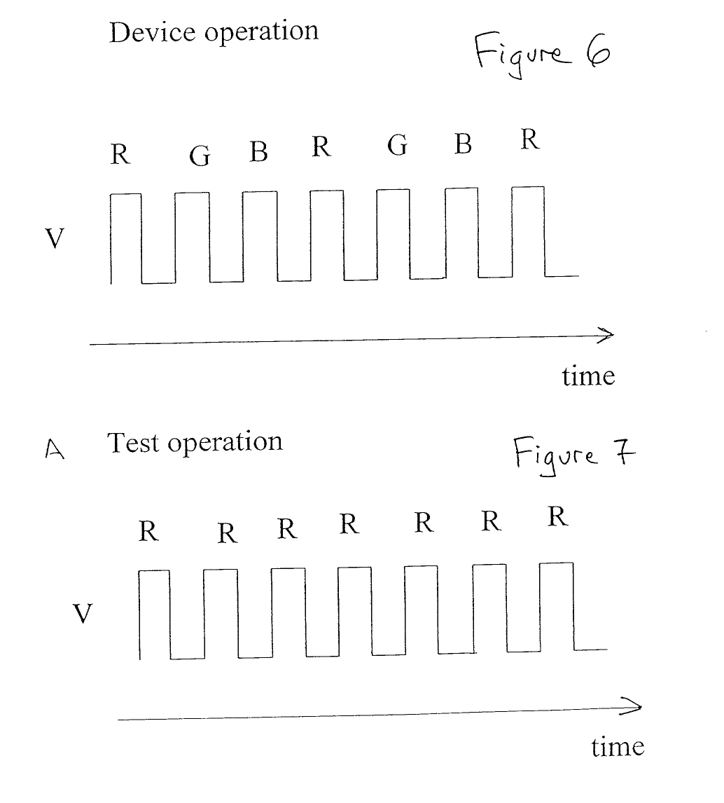

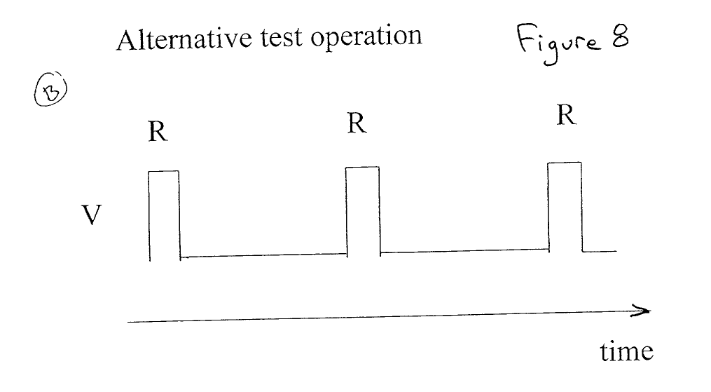

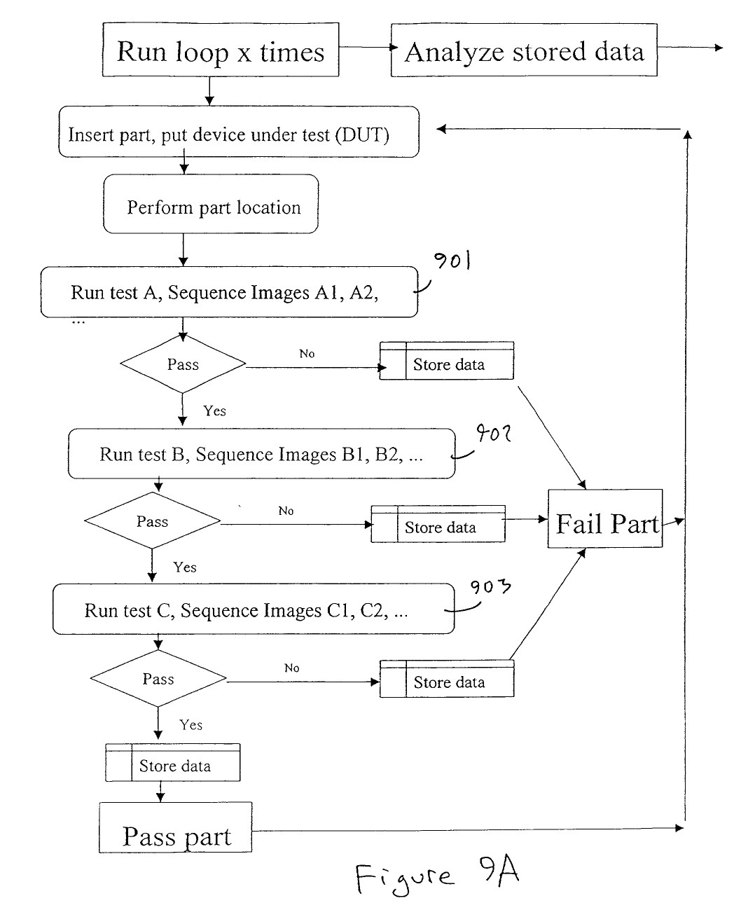

The driving schemes used for the LEDs are illustrated for the device operation (FIG. 6) and test schemes A (FIG. 7) and B (FIG. 8), where “V” is the voltage driving into the device, and the driving schemes move from left to right with time. FIG. 6 illustrates a standard operation for LEDs that are integral with a LCD device. During each time interval, an LED of a different is illuminated. The illumination of all three LEDs produces a white image. For testing, it preferred that a single color is driven by the test apparatus (shown in FIG. 1) to test for uniformity on the LCD for that particular color.

Driving scheme A, illustrated in FIG. 7, illustrates one driving scheme in accordance with the present invention. According to driving scheme A, a single color (i.e. Red) is driven by the test apparatus during each time interval. This driving scheme has an advantage in total test time by testing in monochrome test mode. The test is completed more quickly as each time interval is utilized. However, driving scheme A may not be available if the device under test does not have the ability to test in monochrome. In that case, drive scheme B, illustrated in FIG. 8, may be employed for situations where the product drive scheme can not be redefined for test. Drive scheme B drives a white image as shown in FIG. 6, however, two of three LEDs are shut off. This results in a monochrome illumination of the LCD when the ability of the LEDs to drive a monochrome source is not available. It will be appreciated that although only R (for red) is illustrated as the LED being driven in each illustrative test operation, other colors (such as green and blue) may be substituted to adequately test each LED of the entire device under test 102.

Conventional LCD test devices do not specify drive sequences to examine the subtleties in device uniformity. However, the human eye may be more sensitive to non-uniformities of a particular color. The test apparatus may be configured to test for that color first, in order to increase the throughput of the testing process. Alternatively, to increase the speed of the testing process further, all colors may not need to be tested. A single color may adequately reflect the pass/fail status of the LCD device for the other test for color uniformity.

Additional Tests Made Possible

The method and apparatus of the present invention makes possible additional tests that may be performed to help identify suitable LCD devices for delivery to customers. Two such additional tests are reliable pixel defect tests and uniformity tests for devices that are illuminated in a color sequential manner and/or near-to-the-eye devices. Unlike conventional test equipment, which rely on axial illumination, the present invention makes use of the test apparatus described above that provides side illumination to cause a gradient brightness to be imparted to the device.

Uniformity Testing

The uniformity of the device under test 102 can be viewed as a measure of the degree to which individual pixels in the device deviate from a nominal gray level driven into the device. In other words, each pixel in the device may be illuminated by the LEDs 104 at the same nominal gray level (e.g., all black, all white, or some shade of gray) across the entire device. The gradient drop of light across the device is received at the CCD camera 118, and the image is analyzed by a controller (not shown) such as a computing system. The gray levels of all the pixels establishes a nominal gray level for the entire LCD. The variability of each pixel from the nominal gray level may then be analyzed in order to make a pass/fail determination. In one example, the controller may compare the deviations to some predetermined threshold of acceptance. If the measurements of the device exceed the threshold, the device is failed.

Pixel Defects and Segmentation

For pixel defect detection, a single pixel is examined for variations in nominal operation (e.g., Is the pixel operating? Is the pixel turning completely on and off?). Pixel defects in the test application can be defined as gray level differences from the nominally driven value. The tester can assign a nominal gray level for each pixel that corresponds to the nominal gray level driven by the device. By setting up the tester to compare the gray level differences with respect to the nominally assigned gray levels, the tester can detect the pixel defects that are present within the LCD.

Test Time

To be effective in a high volume manufacturing environment, LCD tests must be performed as quickly as possible. The faster a part can be either failed or passed, the more parts can be produced in a given time frame. For that reason, the inventors have developed further improvements in the process of testing LCDs to more quickly identify whether a part is likely to fail. Two such methods are presented here.

Histogram Equalization

The inventors have noted that color sequential devices are often of a digital nature. This digital nature allows discrete levels of gray to be driven in the test device. Digital images can be addressed with transforms (in the test hardware or software) that provide integrated intensity in specifically chosen gray levels. In image preprocessing, this technique is called histogram equalization. Simply, the image is divided into intensity levels. These intensity levels correspond to the different gray levels that can be obtained within the digital image.

The conventional test solutions do not take into account the possibility of testing a digital device over a limited number of discrete gray levels. However, a tester in accordance with the present invention is capable of testing a digital device over a limited number of gray levels. The limited levels of information allow a tester to take an initial histogram of gray values of the entire image. This data can be rapidly analyzed and, based on the results, a decision to proceed with further defect detection algorithms can be made in less time than with conventional methods.

These nominally assigned intensity levels can be a 1:1 correspondence with respect to the device gray levels. However, to improve the tester CPK or reliability, the tester may have a greater number of intensity levels compared with the device gray levels. Potential ratios include 2:1, 4:1, or the like. Improved reliability of sampling is directly related to the discrete gray levels in the device. This pre-processing routine results in cheaper tester costs (CCD array, camera buffer, and on board memory costs are reduced) and faster testing (algorithm is specifically suited to the gray levels observed in the LCD device).

First-Fail Mode

A test apparatus constructed in accordance with the present invention can be set up in a first fail mode. This speeds the test throughput of an individual device. In addition, a more sophisticated method of first test fail may be obtained by using a genetic (evolutionary or learning) module. In the genetic module, a population of failed parts (size of population is a tradeoff between data processing and the probability of testing the most likely failure) is analyzed for the first failure. The test sequence is then re-ordered based on the probability distribution of the most likely failure.

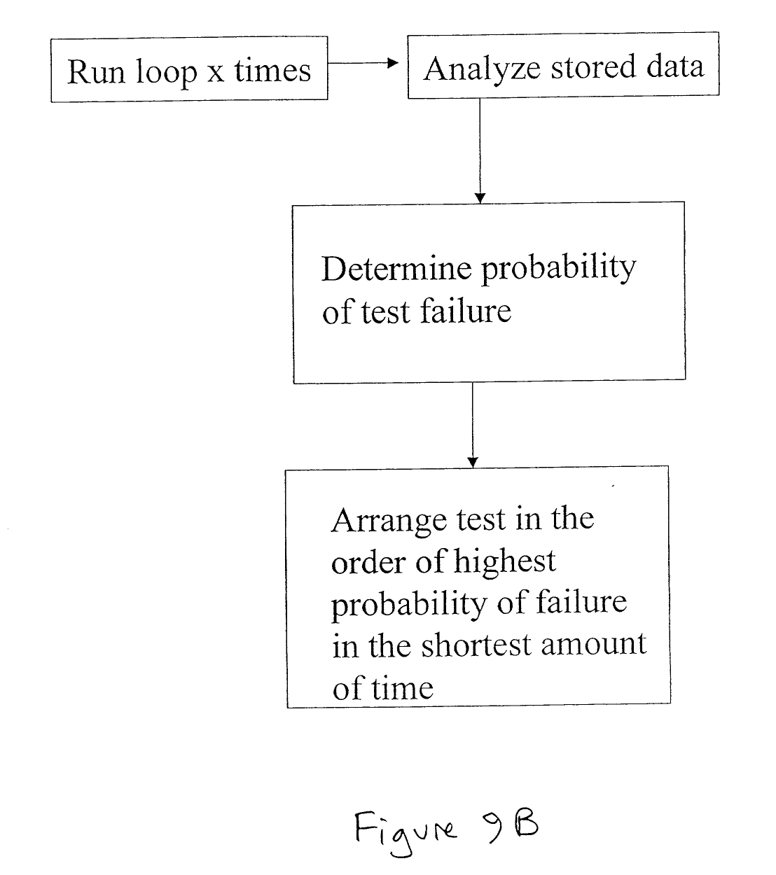

For instance, referring now to the flow chart illustrated in FIG. 9A, one embodiment of the invention includes the following steps. The tester enters a loop performed for each device under test (DUT) in a test lot. The loop includes first inserting the DUT in the test apparatus 100, such as with robotic or other electro-mechanical mechanisms. Less preferably, the DUT may be inserted manually. In one embodiment, the tester, under the control of a suitably programmed controller or processor (i.e., computer control), provides power and control to the LCD to display an image that is then measured. Once the DUT is loaded, the test apparatus 102 performs part location to optically locate the DUT. At that point, a series of tests or sequences of tests may be performed on the DUT. For instance, Test A 901 may be a pixel defect detection test, Test B 902 may be a uniformity test, and Test C 903 may be a brightness test. These specific tests are only given as examples and other tests, more tests, or fewer tests are equally applicable.

At each test (901, 902, 903), the tester measures a predetermined performance parameter of the LCD and compares the measurement to an expected result. This expected result may in the form of a range of acceptable values or a threshold value indicating a maximum or minimum acceptable value. Depending on the measurement, the tester then indicates, at each step, whether the LCD passed or failed the test. If the LCD passed the test, the LCD can then proceed to a next step in the production process, which may include further tests. If the LCD fails any particular test, the part is failed, but more importantly, failure data is stored by the tester for analysis. Passing information may also be stored for those devices that pass all tests. In this way (referring now to FIG. 9B), the tester may perform an analysis of the failure information associated with each failed test in view of the passing information. Based on that analysis, the tester can make determinations about the probabilities that a DUT would fail each particular test (901, 902, 903 of FIG. 9A) being applied. In that way, the tester may rearrange the order in which the tests are given so that the tests with the higher probabilities of failure are performed sooner, thereby shortening the overall time to perform all tests on an entire batch of devices to be tested. The inventors assert that, in view of the present disclosure, one skilled in the art of LCD testers can provide such automated test functionality without undue experimentation.

The above specification, examples and data provide a complete description of the manufacture and use of illustrative embodiments of the invention. However, as will be appreciated by those skilled in the art, many embodiments of the invention, in addition to those illustrated here, can be made without departing from the spirit and scope of the invention.

I claim:

1. An apparatus for testing a liquid crystal display (LCD) device, comprising:
a light emitting device (LED) arranged to side-illuminate the LCD device such that a gradient of light is produced across the LCD device;
a camera device arranged to capture an image of the LCD device that is positioned axially from the device such that a portion of the gradient of light reflected from the LCD device is received by the camera device; and
a controller configured to analyze a set of criteria applied to the image of the LCD device according to a test sequence, and determine whether the LCD device meets the set of criteria.

2. The apparatus of claim 1, wherein the LED is integral to the LCD device such that the LCD device retains the LED after completion of the testing.

3. The apparatus of claim 1, the LED further comprising a package of LEDs that are different colors wherein each LED side-illuminates the LCD separately according to a drive scheme.

4. The apparatus of claim 3, wherein the drive scheme comprises a scheme for side-illuminating the LCD device in a monochrome test mode.

5. The apparatus of claim 3, wherein the drive scheme comprises a scheme for side-illuminating the LCD device with one color by driving a monochrome signal into a set of LEDs and with at least one LED in the set of LEDs disabled.

6. The apparatus of claim 1, the camera device further comprising a CCD camera in combination with lenses, polarizers, a photopic filter, and a polarizing beam splitter for capturing the image of the LCD device.

7. The apparatus of claim 1, the set of criteria further comprising uniformity among the pixels within the LCD device.

8. The apparatus in claim 7, wherein the uniformity among the pixels is measured as a deviation of a group of pixels from a nominally driven gray scale image.

9. The apparatus of claim 1, the set of criteria further comprising a pixel defect test configured to test a gray level difference in a pixel within the LCD device from a nominally driven gray level.

10. The apparatus of claim 1, wherein the image is a digital image such that when the image is analyzed it is divided into intensity levels corresponding to different gray levels obtained within the image.

11. The apparatus of claim 10, wherein a first set of the intensity levels of the image are used to determine whether the LCD device meets the set of criteria and whether further testing is necessary.

12. The apparatus if claim 1, wherein the gradient of light reflected from the LCD device is calibrated out prior to analyzing the set of criteria applied to the image of the LCD device.

13. The apparatus of claim 1, the controller further comprising a genetic module configured to re-order the test sequence by analyzing a population of LCD devices according to when the LCD devices first fail during the test sequence.

14. A method of achieving a pass/fail determination for a liquid crystal display (LCD) according to a set of predetermined characteristics, comprising:
side-illuminating the LCD using a package of light emitting devices (LEDs) wherein each LED has a different color;
capturing an image of the LCD with a camera device wherein the captured image corresponds to light reflected from the LCD in response to the side-illumination;
analyzing the image of the LCD according to the set of predetermined characteristics; and
producing the pass/fail determination in response to the analysis of the image of the LCD.

15. The method of claim 14, wherein side-illuminating the LCD results in a gradient of light intensity across the LCD.

16. The method of claim 15, wherein the gradient of light intensity is calibrated out prior to analyzing the image of the LCD according to the set of predetermined characteristics.

17. The method of claim 14, wherein side-illuminating the LCD further comprises each LED side-illuminating the LCD separately according to a drive scheme.

18. The method of claim 17, wherein the drive scheme further comprises a scheme for side-illuminating the LCD in a monochrome test mode.

19. The method of claim 17, wherein the drive scheme further comprises a scheme for side-illuminating the LCD using a single LED of one color.

20. The method of claim 17, wherein the drive scheme further comprises a scheme for side-illuminating the LCD using a plurality of LEDs by driving a monochromatic image into the plurality of LEDs while disabling a subset of the plurality of LEDs.

21. The method of claim 14, wherein analyzing the image further comprises an analysis of color uniformity of the image.

22. The method of claim 14, wherein analyzing the image further comprises an analysis of pixel defects of the image.

23. The method of claim 14, wherein analyzing the image further comprises an analysis of the image that reveals shorts and open circuit conditions for a multiplexer associated with each pixel of the LCD.

24. The method of claim 14, wherein analyzing the image further comprises an iterative process for determining an order of analysis in response to which characteristics of the set of characteristics result in a higher number of failures.

25. An apparatus for producing a pass/fail determination for a liquid crystal display (LCD) according to user-defined tolerances, comprising:
a means for side-illuminating the LCD is arranged to side-illuminate the LCD using a package of light emitting devices (LEDs) wherein each LED has a different color;
a means for capturing an image of the LCD is arranged to capture an image of the LCD with a camera device wherein the image corresponds to light reflected from the LCD in response to the side-illumination;
a means for analyzing the image of the LCD is arranged to analyze the image of the LCD according to the set of predetermined characteristics; and
a means for producing the pass/fail determination is arranged to produce the pass/fail determination in response to the analysis of the image of the LCD.

26. The apparatus of claim 25, the means for producing the pass/fail determination further comprising a genetic module configured to re-order the test sequence by analyzing a population of LCD devices according to when the LCD devices first fail during the test sequence.

27. The apparatus of claim 25, wherein the package of LEDs are integral to the LCD such that the LCD retains the LED after completion of the testing.

28. The apparatus of claim 25, wherein each LED side-illuminates the LCD separately according to a drive scheme.

29. The apparatus of claim 3, wherein the drive scheme comprises a scheme for side-illuminating the LCD device in a monochrome test mode.

30. The apparatus of claim 3, wherein the drive scheme comprises a scheme for side-illuminating the LCD using a single LED of one color by side-illuminating the LCD with a white image while turning off the other LEDs of other colors.
